(19) United States
(12) Patent Application Publication
(10) Pub. No.: US 2011/0318558 A1
(43) Pub. Date: Dec. 29, 2011

(54) COATING, ARTICLE COATED WITH COATING, AND METHOD FOR MANUFACTURING ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); LI-QUAN PENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/074,108

(22) Filed: Mar. 29, 2011

(30) Foreign Application Priority Data
Jun. 24, 2010 (CN) 201010208726.6

(51) Int. Cl. B32B 9/04; C23C 14/16; C23C 14/32

(52) U.S. Cl. 428/220; 428/448; 204/192.38

(57) ABSTRACT

A coating includes a bonding layer comprised of TiNbN, a transition layer comprised of TiSiNbN formed on the bonding layer, and an outmost layer comprised of TiSiNbN formed on the transition layer. The percentage of atomics Ti and Nb in the outmost layer are respectively lower than the percentage of atomics Ti and Nb in the transition layer, and the percentage of atomic Si in the outmost layer are higher than the percentage of atomic Si in the transition layer.

### BACKGROUND

1. Technical Field

The exemplary disclosure generally relates to coatings, and particularly relates to an article coated with a coating, and method for manufacturing the article.

2. Description of Related Art

Physical vapor deposition (PVD) has been used to form a coating on metal bases of cutting tools or molds. Materials for PVD coating need to have excellent hardness and toughness. Titanium nitride (TiN) and Titanium-aluminum nitride (TiAlN) are materials currently in use, but are not always hard and resistant enough to abrasion to satisfy demands.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary coating, article coated with the coating and method for manufacturing the article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of coating.

FIG. 2 is a cross-sectional view of an article coated with the coating in FIG. 1.

FIG. 3 is a schematic view of an arc ion plating apparatus for manufacturing the article in FIG. 2.

### DETAILED DESCRIPTION

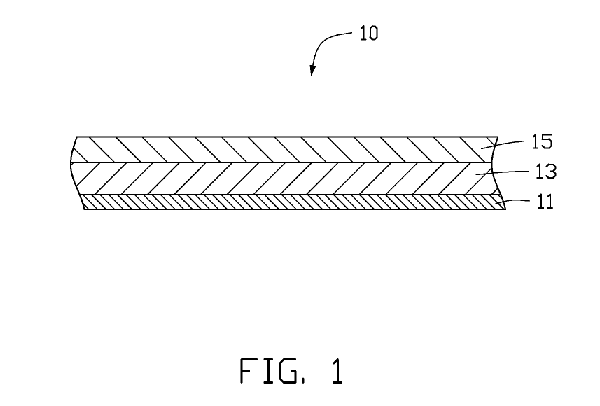

FIG. 1 shows a coating 10 including a bonding layer 11, a transition layer 13 formed on the bonding layer 11, and an outmost layer 15 formed on the transition layer 13.

The bonding layer 11 is a Titanium Niobium Nitride (TiNbN) layer. In the bonding layer 11, the percentage of atomic Ti is about 50% to about 60%; the percentage of atomic Nb is about 4% to about 6%; the percentage of atomic N is about 35% to about 45%. In this exemplary embodiment, the percentage of atomic Ti, Nb, and N are about 55%, 5%, and 40%, respectively.

The transition layer 13 is directly formed on the bonding layer 11. The transition layer is a Titanium Silicon Niobium Nitride (TiSiNbN) layer. In the transition layer 13, the percentage of atomic Ti is about 35% to about 45%; the concentration of element Si is about 20% to about 30%; the percentage of atomic Nb is about 2% to about 5%; the percentage of atomic N is about 28% to about 36%. In this exemplary embodiment, the percentage of atomic Ti is about 40%, the percentage of atomic Si is about 25%, the percentage of atomic Nb is about 3%, and the percentage of atomic N is about 32%.

The outmost layer 15 is directly formed on the transition layer 13. The outmost layer 15 also is a TiSiNbN layer. Being distinct from the transition layer 13, the outmost layer 15 contains element Ti with the atomic percentage of about 15% to about 25%, which is lower than in the transition layer 13. The percentage of atomic Nb is about 0.5% to about 2.5%, which is lower than in the transition layer 13. The percentage of atomic Si is about 40% to about 55%, which is higher than in the transition layer 13. The percentage of atomic N is about 28% to about 36%. In this exemplary embodiment, the percentage of atomic Ti is about 20%; the percentage of atomic Nb is about 2%; the percentage of atomic Si is about 45%; and the percentage of atomic N is about 33%.

The coating 10 has a thickness of about 1 μm to about 8 μm, and in this exemplary embodiment is about 3 μm to 5 μm. The thickness of the transition layer 13 may be about 85% to about 95% of the total thickness of the coating 10. The thickness of the bonding layer 11 may be about 3% to about 10% of the total thickness of the coating 10. The thickness of the outmost layer 15 may be about 2% to about 5% of the total thickness of the coating 10. The coating 10 has a micro hardness above 40 GPa and may be formed by arc ion plating.

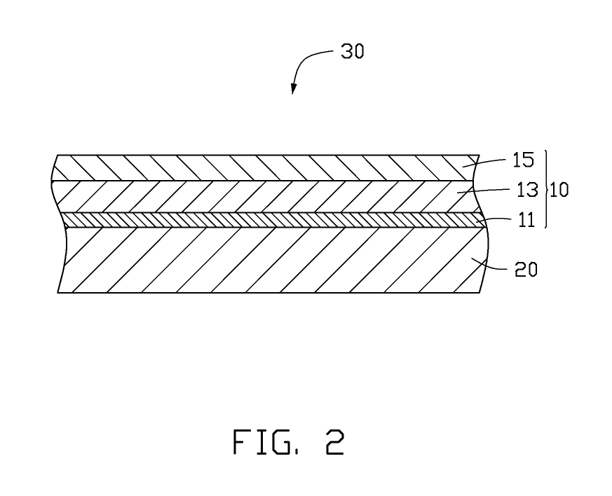

FIG. 2 shows an exemplary article 30 including a hard substrate 20 and the coating 10 formed on the substrate 20. The substrate 20 may be made of metal, such as high speed steel, hard alloy, cermet, ceramic, or stainless steel. The article 30 may be a cutting tool, a mold, a precision measuring tool, or a device housing.

The bonding layer 11, which is directly bonded to the substrate 20, is comprised of TiNbN and has a thermal expansion closely matching the thermal expansion of the materials of the substrate 20. Thus, the bonding layer 11 may improve binding force between the substrate 20 and the coating 10, and the coating 10 can be firmly attached to the substrate 20. In addition, due to the properties of the high concentration of Si₃N₄ phase contained in the TiSiNbN of the outmost layer 15, the coating 10 has high hardness, low thermal conductivity, and good lubricity under high temperature. Furthermore, the element Nb contained in the coating 10 improves the toughness and abrasion resistance of the coating 10.

An exemplary method for manufacturing the article 30 may include at least the following steps.

Referring to FIG. 2, the hard substrate 20 is provided.

The coating 10 is coated on the substrate 20 by arc ion plating in the following steps.

First, the substrate 20 may be pretreated by ultrasonic cleaning in a solution containing alcohol or acetone, to remove impurities such as grease or dirt. Then the substrate 20 is dried.

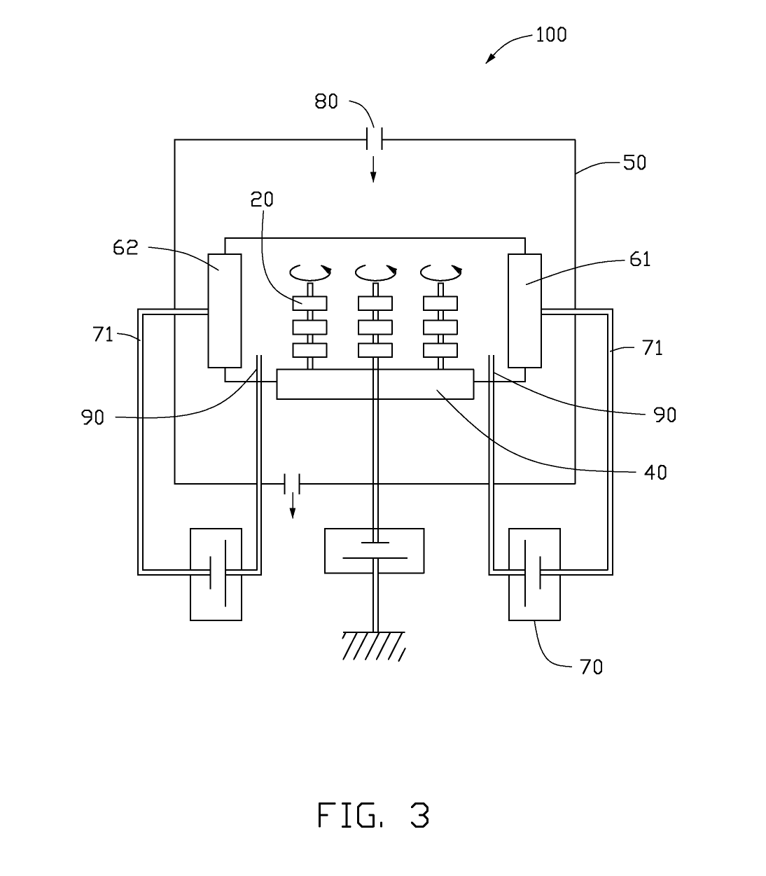

The bonding layer 11 is formed on the substrate 20. The substrate 20 is retained on a rotary bracket 40 in a vacuum chamber 50 of an arc ion plating apparatus 100 as shown in FIG. 3. A Ti—Nb alloy target 61 containing atomic Nb of about 7 wt %˜10 wt % and a silicon target 62 are respectively connected to two cathodes 71 of an arc power supply 70. The vacuum chamber 50 is evacuated to maintain a background vacuum level of about 1.0×10⁻³ Pa to about 9.0×10⁻³ Pa. Pure argon is fed into the vacuum chamber 50 at a flux of about 200 Standard Cubic Centimeters per Minute (sccm) to about 300 sccm from a gas inlet 80, and pure nitrogen as a reaction gas is introduced into the vacuum chamber 50 to maintain a reaction atmosphere of about 0.1 Pa to 0.2 Pa. The flux of the nitrogen is about 280 sccm to about 300 sccm. A DC bias voltage is applied to the substrate 20 in a range of about −200 to −400 volts. At the same time, arc discharge is generated by applying a current of about 50 A to about 80 A between the Ti—Nb alloy target and a corresponding anode 90 for about 5 minutes to about 10 minutes, thereby forming the bonding layer 11 comprised of TiNbN on the substrate 20.

Then, the DC bias voltage is adjusted to about −150 to −250 volts. The current applied to the Ti—Nb alloy target 50 is adjusted to about 70˜100 A, and a current of about 40 A to about 60 A is applied between the silicon target 60 and a corresponding anode 90 for about 30 minutes to about 60 minutes, to deposit the transition layer 13 comprised of TiSiNbN on the bonding layer 11. In this step, the flux of the argon and the flux of the nitrogen are maintained the same as for depositing the bonding layer 11.

Then, the current applied to the Ti—Nb alloy target is adjusted to about 40˜60 A, and the current applied to the silicon target is adjusted to about 70˜100, to deposit the outmost layer 15 comprised of TiSiNbN on the transition layer 13. This step continues for about 30 minutes to about 60 minutes. In this step, the DC bias voltage, the flux of the argon, and the flux of the nitrogen are maintained the same as for depositing the transition layer 13.

Once deposition is finished, the DC bias voltage and the currents applied to the Ti—Nb alloy target and the silicon target are turned off, and the introduction of argon and nitrogen are stopped. Air is then introduced into the vacuum chamber 50 after the coating 10 cooled down. Then the substrate 20 with the coating 10 can be taken out.

It is to be understood that a step of plasma cleaning the substrate 20 may be performed in the vacuum chamber 50 before depositing the bonding layer 11.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coating, comprising:
a bonding layer comprised of TiNbN;
a transition layer comprised of TiSiNbN formed on the bonding layer; and
an outmost layer comprised of TiSiNbN formed on the transition layer, the percentage of atomic Ti and Nb in the outmost layer being respectively lower than the percentage of atomic Ti and Nb in the transition layer, and the percentage of atomic Si in the outmost layer being higher than the percentage of atomic Si in the transition layer.

2. The coating as claimed in claim 1, wherein in the bonding layer, the percentage of atomic Ti is about 50% to about 60%; the percentage of atomic Nb is about 4% to about 6%; the percentage of atomic N is about 35% to about 45%.

3. The coating as claimed in claim 2, wherein in the bonding layer, the percentage of atomic Ti is about 55%; the percentage of atomic Nb is about 5%; the percentage of atomic N is about 40%.

4. The coating as claimed in claim 1, wherein in the transition layer, the percentage of atomic Ti is about 35% to about 45%; the concentration of element Si is about 20% to about 30%; the percentage of atomic Nb is about 2% to about 5%; the percentage of atomic N is about 28% to about 36%.

5. The coating as claimed in claim 4, wherein in the transition layer, the percentage of atomic Ti is about 40%; the percentage of atomic Si is about 25%; the percentage of atomic Nb is about 3%; the percentage of atomic N is about 32%.

6. The coating as claimed in claim 1, wherein in the outmost layer, the percentage of atomic Ti is about 15% to about 25%; the percentage of atomic Nb is about 0.5% to about 2.5%; the percentage of atomic Si is about 40% to about 55%; the percentage of atomic of the element N is about 28% to about 36%.

7. The coating as claimed in claim 6, wherein in the outmost layer, the percentage of atomic Ti is about 20%; the percentage of atomic Nb is about 2%; the percentage of atomic Si is about 45%; the percentage of atomic N is about 33%.

8. The coating as claimed in claim 1, wherein the coating has a total thickness of about 1 μm to about 8 μm; the thickness of the transition layer is about 85% to about 95% of the thickness of the coating; the thickness of the bonding layer is about 3% to about 10% of the thickness of the coating; the thickness of the outmost layer is about 2% to about 5% of the thickness of the coating.

9. An article, comprising:
a substrate; and
a coating comprising:
a bonding layer comprised of TiNbN formed on the substrate;
a transition layer comprised of TiSiNbN formed on the bonding layer; and
an outmost layer comprised of TiSiNbN formed on the transition layer, the percentage of atomics Ti and Nb in the outmost layer being respectively lower than the percentage of atomics Ti and Nb in the transition layer, and the percentage of atomic Si in the outmost layer being higher than the percentage of atomic Si in the transition layer.

10. The article as claimed in claim 9, wherein in the bonding layer, the percentage of atomic Ti is about 50% to about 60%; the percentage of atomic Nb is about 4% to about 6%; the percentage of atomic N is about 35% to about 45%.

11. The article as claimed in claim 9, wherein in the transition layer, the percentage of atomic Ti is about 35% to about 45%; the concentration of element Si is about 20% to about 30%; the percentage of atomic Nb is about 2% to about 5%; the percentage of atomic N is about 28% to about 36%.

12. The article as claimed in claim 9, wherein in the outmost layer, the percentage of atomic Ti is about 15% to about 25%; the percentage of atomic Nb is about 0.5% to about 2.5%; the percentage of atomic Si is about 40% to about 55%; the percentage of atomic of the element N is about 28% to about 36%.

13. The article as claimed in claim 9, wherein the substrate is made of one of the materials of high speed steel, hard alloy, cermet, ceramic, and stainless steel.

14. The article as claimed in claim 9, wherein the article is one of the cutting tool, mold, precision measuring tool, and housing of electronic devices.

15. The coating as claimed in claim 9, wherein the bonding layer is deposited by magnetron sputtering.

16. A method for manufacturing an article comprising steps of:
providing hard substrate made of metal or ceramic; and
depositing a coating on the substrate by arc ion plating, the coating including: a bonding layer comprised of TiNbN formed on the substrate; a transition layer comprised of TiSiNbN formed on the bonding layer; and an outmost layer comprised of TiSiNbN formed on the transition layer, the percentage of atomics Ti and Nb in the outmost layer being respectively lower than the percentage of atomics Ti and Nb in the transition layer, and the percentage of atomic Si in the outmost layer being higher than the percentage of atomic Si in the transition layer.

17. The method of claim 16, wherein during depositing the bonding layer on the substrate, the substrate is retained in a vacuum chamber of an arc ion plating apparatus; a Ti—Nb alloy target containing element Nb of about 7 wt %˜10 wt % is used; argon is fed into the vacuum chamber at a flux of about 200 sccm to 300 sccm; nitrogen is fed into to the vacuum chamber at a flux of about 280 sccm to 300 sccm; a DC bias voltage is applied to the substrate in a range of about −200 to −400 volts; a current of about 50 A to 80 A is applied to the Ti—Nb alloy target for about 5 minutes to about 10 minutes.

18. The method of claim 16, wherein during depositing the transition layer on the bonding layer, the substrate is retained in a vacuum chamber of arc ion plating apparatus; a Ti—Nb alloy target containing element Nb of about 7 wt %˜10 wt % and a silicon target are used; argon is fed into the vacuum chamber at a flux of about 200 sccm to 300 sccm; nitrogen is fed into to the vacuum chamber at a flux of about 280 sccm to 300 sccm; a DC bias voltage is applied to the substrate in a range of about −150 to −250 volts; a current of about 70 A to 100 A is applied to the Ti—Nb alloy target, and a current of about 40 A to 60 A is applied to the silicon target for about 30 minutes to about 60 minutes.

19. The method of claim 16, wherein during depositing the outmost layer on the transition layer, the substrate is retained in a vacuum chamber of arc ion plating apparatus; a Ti—Nb alloy target containing element Nb of about 7 wt %˜10 wt % and a silicon target are used; argon is fed into the vacuum chamber at a flux of about 200 sccm to 300 sccm; nitrogen is fed into to the vacuum chamber at a flux of about 280 sccm to 300 sccm; a DC bias voltage is applied to the substrate in a range of about −150 to −250 volts; a current of about 40 A to 60 A is applied to the Ti—Nb alloy target, and a current of about 7 A to 100 A is applied to the silicon target for about 3 minutes to about 5 minutes.

20. The method of claim 16, further comprising a step of plasma cleaning the substrate in the vacuum chamber before depositing the bonding layer.
